(19) United States
(12) Patent Application Publication
(10) Pub. No.: US 2018/0261535 A1
(43) Pub. Date: Sep. 13, 2018

(54) METHOD OF MAKING WIRING BOARD WITH DUAL ROUTING CIRCUITRIES INTEGRATED WITH LEADFRAME

(71) Applicant: BRIDGE SEMICONDUCTOR CORP., Taipei City (TW)

(72) Inventors: Charles W. C. LIN, Taipei City (TW); Chia-Chung WANG, Taipei City (TW)

(21) Appl. No.: 15/976,106

(22) Filed: May 10, 2018

Related U.S. Application Data
(63) Continuation-in-part of application No. 15/247,828, filed on Aug. 25, 2016.
Application No. 15/247,828 is a continuation-in-part of application No. 14/746,792, filed on Jun. 22, 2015, now abandoned.
(60) Provisional application No. 62/092,196, filed on Dec. 15, 2014.
(60) Provisional application No. 62/121,450, filed on Feb. 26, 2015.

(51) Int. Cl. H01L 23/498; H01L 21/48; H01L 23/13; H01L 21/683; H01L 23/544; H01L 23/538

(52) U.S. Cl. CPC H01L 23/49861; H01L 21/4857; H01L 21/481; H01L 23/13; H01L 21/6835; H01L 24/16; H01L 23/5389; H01L 23/5383; H01L 23/5386; H01L 2221/68345; H01L 2223/54426; H01L 23/544

(57) ABSTRACT

The wiring board includes a first routing circuitry and a second routing circuitry integrated with a leadframe. The first routing circuitry is laterally surrounded by the leadframe and can provide a first level routing for a semiconductor device disposed thereon. The second routing circuitry is disposed beyond the space laterally surrounded by the leadframe and extends over the leadframe and is electrically connected to the first routing circuitry and metal leads of the leadframe to provide a second level routing.

### CROSS REFERENCE TO RELATED APPLICATIONS

This application is a continuation-in-part of U.S. application Ser. No. 15/247,828 filed Aug. 25, 2016. The U.S. application Ser. No. 15/247,828 is a continuation-in-part of U.S. application Ser. No. 14/746,792 filed Jun. 22, 2015, which claims the priority benefit of U.S. Provisional Application Ser. No. 62/092,196 filed Dec. 15, 2014 and the priority benefit of U.S. Provisional Application Ser. No. 62/121,450 filed Feb. 26, 2015. The entirety of each of said Applications is incorporated herein by reference.

### FIELD OF THE INVENTION

The present invention relates to a method of making a wiring board and, more particularly, to a method of making a wiring board having integrated dual routing circuitries within and beyond a space laterally surrounded by of a leadframe.

### DESCRIPTION OF RELATED ART

Market trends of multimedia devices demand for faster and slimmer designs. One of the approaches is to assemble multiple devices on a wiring board with stacking configuration so that the electrical performance can be improved and the form-factor can be further minimized. U.S. Pat. No. 6,590,281 discloses a leadframe-based semiconductor package having a first chip electrically connected to a first bonding region of the leadframe by bonding wire, and a second chip mounted on the first chip and electrically connected to a second bonding region by solder ball or conductive adhesive. The disclosed board is made of metal leads with specific etching pattern to accommodate the stacked chips. However, since metal leads are the only connection channels and have limited routing capability, this board is not suitable for high performance, high input/output (I/O) device. Alternatively, as described in U.S. Pat. No. 8,421,199, the wiring board has a routing circuitry disposed on a dielectric layer and electrically connected to a plurality of metal leads. As the metal leads are disposed underneath the routing circuitry and serves as contacting terminals for next level assembly, this board does not have dual channels needed for 3D stacking of chips.

For the reasons stated above, and for other reasons stated below, developing a wiring board having multiple connection channels for 3D stacking and each channel has flexible routing capability would be highly desirable.

### SUMMARY OF THE INVENTION

A primary objective of the present invention is to provide a method of making a wiring board having first and second routing circuitries integrated with a leadframe so as to enable 3D stacking of semiconductor chips with high routing flexibility. For instance, the first routing circuitry can be configured as primary connection channel for a first chip, and metal leads of the leadframe provide another connection channel for a second chip. The first chip and the second chip are then connected together through the first routing circuitry, the leadframe and the second routing circuitry. The two routing circuitries integrated with leadframe can offer the shortest possible interconnection length for the stacked chips, thereby reducing the inductance and improving the electrical performance of the assembly.

Another objective of the present invention is to provide a method of making a wiring board having resin-bonded metal leads that surround routing circuitry and serve as stiffener, thereby allowing a stable mechanical structure that can endure thermal cycling without suffering warping, and cracking.

In accordance with the foregoing and other objectives, the present invention provides a method of making a wiring board, comprising: providing a first routing circuitry that includes first electrical conductors and second electrical conductors at two opposite sides thereof, respectively, wherein the first electrical conductors and the second electrical conductors are electrically connected to each other; providing a leadframe that laterally surrounds the first routing circuitry and includes a plurality of metal leads and a first binding resin, wherein the first binding resin fills in spaces between the metal leads; and forming a second routing circuitry that is disposed over the first routing circuitry and laterally extends over the leadframe, wherein the second routing circuitry includes at least one dielectric layer and at least one wiring layer in an alternate fashion, and the wiring layer of the second routing circuitry is electrically coupled to the second electrical conductors of the first routing circuitry and the metal leads.

In another aspect, the present invention provides a method of making another wiring board, comprising: providing a first routing circuitry that includes first electrical conductors and second electrical conductors at two opposite sides thereof, respectively, wherein the first electrical conductors and the second electrical conductors are electrically connected to each other; providing a leadframe that laterally surrounds the first routing circuitry and includes a plurality of metal leads; and forming a second routing circuitry that is disposed over the first routing circuitry and laterally extends over the leadframe, wherein the second routing circuitry includes at least one dielectric layer and at least one wiring layer in an alternate fashion, and a portion of the dielectric layer fills in spaces between the metal leads and binds peripheral edges of the first routing circuitry, and the wiring layer is electrically coupled to the second electrical conductors of the first routing circuitry and the metal leads.

Unless specifically indicated or using the term “then” between steps, or steps necessarily occurring in a certain order, the sequence of the above-mentioned steps is not limited to that set forth above and may be changed or reordered according to desired design.

The method of making a wiring board according to the present invention has numerous advantages. For instance, providing the leadframe surrounding the first routing circuitry is particularly advantageous as the metal leads of the leadframe can offer horizontal routing and vertical connecting channels between two opposite sides of the wiring board. Combining the subcomponent with the leadframe can provide a stable platform for forming the second routing circuitry thereon. Additionally, the two-stage formation of the wiring board can avoid serious warping problem when multiple layers of routing circuitries are needed.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of the structure with a routing layer formed on a sacrificial carrier in accordance with the first embodiment of the present invention;

FIGS. 3 and 4 are cross-sectional and top perspective views, respectively, of the structure of FIGS. 1 and 2 further provided with a dielectric layer and a wiring layer to finish the formation of a first routing circuitry on the sacrificial carrier in accordance with the first embodiment of the present invention;

FIGS. 5 and 6 are cross-sectional and top perspective views, respectively, of a diced state of the panel-scale structure of FIGS. 3 and 4 in accordance with the first embodiment of the present invention;

FIGS. 7 and 8 are cross-sectional and top perspective views, respectively, of a subcomponent corresponding to a diced unit in FIGS. 5 and 6 in accordance with the first embodiment of the present invention;

FIGS. 9, 10 and 11 are cross-sectional, top perspective and bottom perspective views, respectively, of a textured metal sheet in accordance with the first embodiment of the present invention;

FIGS. 12, 13 and 14 are cross-sectional, top perspective and bottom perspective views, respectively, of the structure of FIGS. 9, 10 and 11 further provided with a first binding resin in accordance with the first embodiment of the present invention;

FIGS. 15, 16 and 17 are cross-sectional, top perspective and bottom perspective views, respectively, of the structure of FIGS. 12, 12 and 14 formed with an aperture to finish the fabrication of an untrimmed leadframe in accordance with the first embodiment of the present invention;

FIGS. 18, 19 and 20 are cross-sectional, top perspective and bottom perspective views, respectively, of the structure of FIGS. 15, 16 and 17 further provided with the subcomponent of FIGS. 7 and 8 in accordance with the first embodiment of the present invention;

FIGS. 21, 22 and 23 are cross-sectional, top perspective and bottom perspective views, respectively, of the structure of FIGS. 18, 19 and 20 further provided with a second binding resin in accordance with the first embodiment of the present invention;

FIGS. 24 and 25 are cross-sectional and bottom perspective views, respectively, of the structure of FIGS. 21, 22 and 23 further provided with a first dielectric layer, a metal layer and via openings in accordance with the first embodiment of the present invention;

FIGS. 26 and 27 are cross-sectional and bottom perspective views, respectively, of the structure of FIGS. 24 and 25 further provided with a first wiring layer in accordance with the first embodiment of the present invention;

FIGS. 28 and 29 are cross-sectional and bottom perspective views, respectively, of the structure of FIGS. 26 and 27 further provided with a second dielectric layer and a second wiring layer in accordance with the first embodiment of the present invention;

FIGS. 30 and 31 are cross-sectional and top perspective views, respectively, of the structure of FIGS. 28 and 29 after removal of the sacrificial carrier to finish the fabrication of an untrimmed wiring board in accordance with the first embodiment of the present invention;

FIGS. 32 and 33 are cross-sectional and top perspective views, respectively, of the wiring board trimmed from the structure of FIGS. 30 and 31 in accordance with the first embodiment of the present invention;

FIG. 34 is a cross-sectional view of the structure of FIG. 15 further provided with a subcomponent in accordance with the second embodiment of the present invention;

FIG. 35 is a cross-sectional view of the structure of FIG. 34 further provided with a first dielectric layer and a first wiring layer in accordance with the second embodiment of the present invention;

FIG. 36 is a cross-sectional view of the structure of FIG. 35 after removal of the sacrificial carrier to finish the fabrication of an untrimmed wiring board in accordance with the second embodiment of the present invention;

FIG. 37 is a cross-sectional view of the structure of FIG. 15 further provided with a first routing circuitry in accordance with the third embodiment of the present invention;

FIG. 38 is a cross-sectional view of the structure of FIG. 37 further provided with a first dielectric layer and a first wiring layer to finish the fabrication of an untrimmed wiring board in accordance with the third embodiment of the present invention;

FIGS. 39, 40 and 41 are cross-sectional, top perspective and bottom perspective views, respectively, of a leadframe in accordance with the fourth embodiment of the present invention;

FIGS. 42, 43 and 44 are cross-sectional, top perspective and bottom perspective views, respectively, of the structure of FIGS. 39, 40 and 41 further provided with the subcomponent of FIGS. 7 and 8 in accordance with the fourth embodiment of the present invention;

FIGS. 45, 46 and 47 are cross-sectional, top perspective and bottom perspective views, respectively, of the structure of FIGS. 42, 43 and 44 further provided with a first dielectric layer, a metal layer and via openings in accordance with the fourth embodiment of the present invention;

FIGS. 48 and 49 are cross-sectional and bottom perspective views, respectively, of the structure of FIGS. 45, 46 and 47 further provided with a first wiring layer in accordance with the fourth embodiment of the present invention;

FIGS. 50 and 51 are cross-sectional and bottom perspective views, respectively, of the structure of FIGS. 48 and 49 further provided with a second dielectric layer and a second wiring layer in accordance with the fourth embodiment of the present invention;

FIGS. 52 and 53 are cross-sectional and top perspective views, respectively, of the structure of FIGS. 50 and 51 after removal of the sacrificial carrier to finish the fabrication of an untrimmed wiring board in accordance with the fourth embodiment of the present invention;

FIGS. 54 and 55 are cross-sectional and top perspective views, respectively, of the wiring board trimmed from the structure of FIGS. 52 and 53 in accordance with the fourth embodiment of the present invention;

FIG. 56 is a cross-sectional view of the structure of FIG. 54 further provided with a first semiconductor device in accordance with the fourth embodiment of the present invention;

FIG. 57 is a cross-sectional view of the structure of FIG. 56 further provided with a second semiconductor device and solder balls in accordance with the fourth embodiment of the present invention; and

FIG. 58 is a cross-sectional view of another wiring board in accordance with the fifth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the disclosure of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

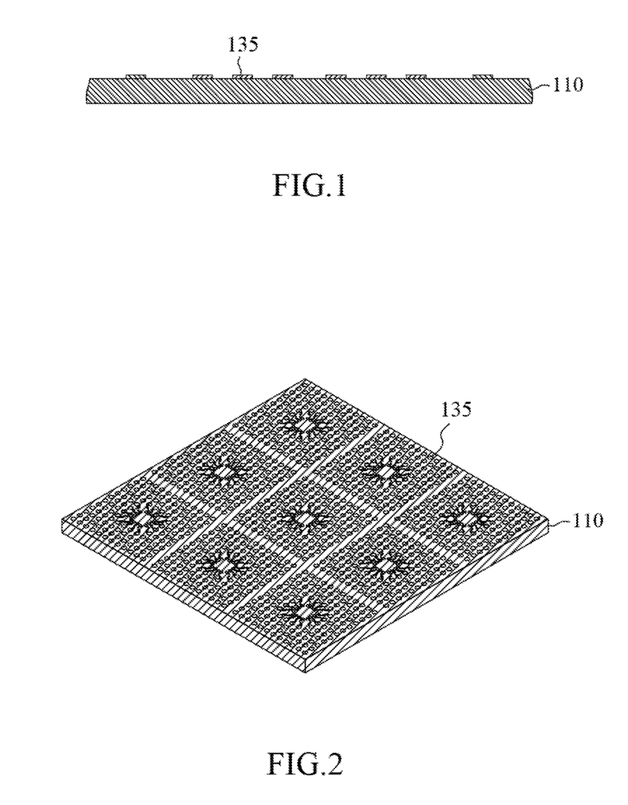

FIGS. 1-31 are schematic views showing a method of making an untrimmed wiring board that includes a first routing circuitry, a leadframe, a second binding resin and a second routing circuitry in accordance with the first embodiment of the present invention.

FIGS. 1 and 2 are cross-sectional and top perspective views, respectively, of the structure with a routing layer 135 formed on a detachable sacrificial carrier 110 by metal deposition and metal patterning process. In this illustration, the sacrificial carrier 110 is a single-layer structure, and typically is made of copper, aluminum, iron, nickel, tin, stainless steel, silicon, or other metals or alloys, but any other conductive or non-conductive material also may be used. The routing layer 135 can be pattern deposited by numerous techniques, such as electroplating, electroless plating, evaporating, sputtering or their combinations, or be thin-film deposited followed by a metal patterning process. For a conductive sacrificial carrier 110, the routing layer 135 is deposited typically by plating of metal. The metal patterning techniques include wet etching, electro-chemical etching, laser-assist etching, and their combinations with an etch mask (not shown) thereon that defines the routing layer 135. In this embodiment, the sacrificial carrier 110 is made of an iron-based material, and the routing layer 135 is made of copper.

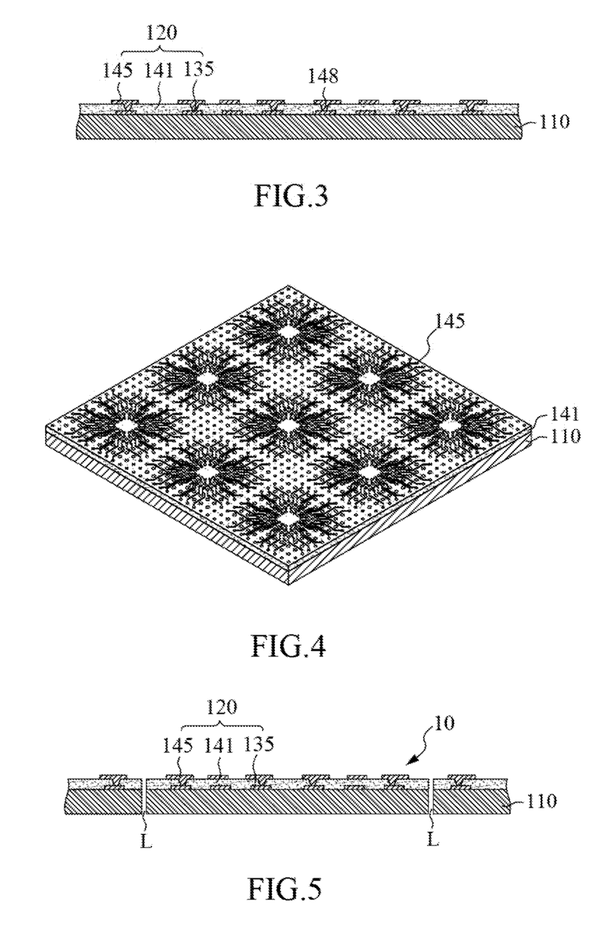

FIGS. 3 and 4 are cross-sectional and top perspective views, respectively, of the structure with a dielectric layer 141 and a wiring layer 145 serially formed in an alternate fashion. The dielectric layer 141 is deposited typically by lamination or coating, and can be made of epoxy resin, glass-epoxy, polyimide, or the like. The wiring layer 145 extends laterally on the dielectric layer 141 and includes metallized vias 148 in the dielectric layer 141. As a result, the wiring layer 145 can be electrically coupled to the routing layer 135 through the metallized vias 148.

The wiring layer 145 can be deposited as a single layer or multiple layers by any of numerous techniques, such as electroplating, electroless plating, evaporating, sputtering, or their combinations. For instance, the wiring layer 145 can be deposited by first dipping the structure in an activator solution to render the dielectric layer 141 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the wiring layer 145 by any of numerous techniques including wet etching, electro-chemical etching, laser-assist etching, and their combinations, with an etch mask (not shown) thereon that defines the wiring layer 145.

At this stage, the formation of a first routing circuitry 120 on the sacrificial carrier 110 is accomplished. In this illustration, the first routing circuitry 120 is a multi-layered buildup circuitry and includes the routing layer 135, the dielectric layer 141 and the wiring layer 145.

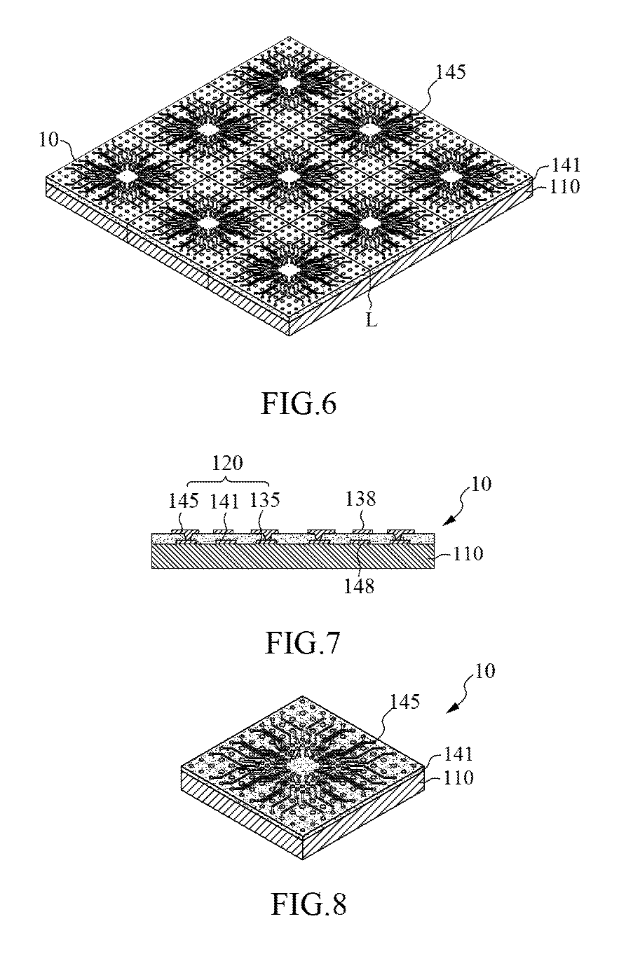

FIGS. 5 and 6 are cross-sectional and top perspective views, respectively, of the panel-scale structure of FIGS. 3 and 4 diced into individual pieces. In this illustration, the panel-scale structure is singulated into individual subcomponent 10 along dicing lines “L”.

FIGS. 7 and 8 are cross-sectional and top perspective views, respectively, of the individual subcomponent 10 that includes the sacrificial carrier 110 and the first routing circuitry 120. In this illustration, the first routing circuitry 120 is a multi-layered buildup circuitry, and includes first electrical conductors 138 and second electrical conductors 148 at its two opposite sides, respectively.

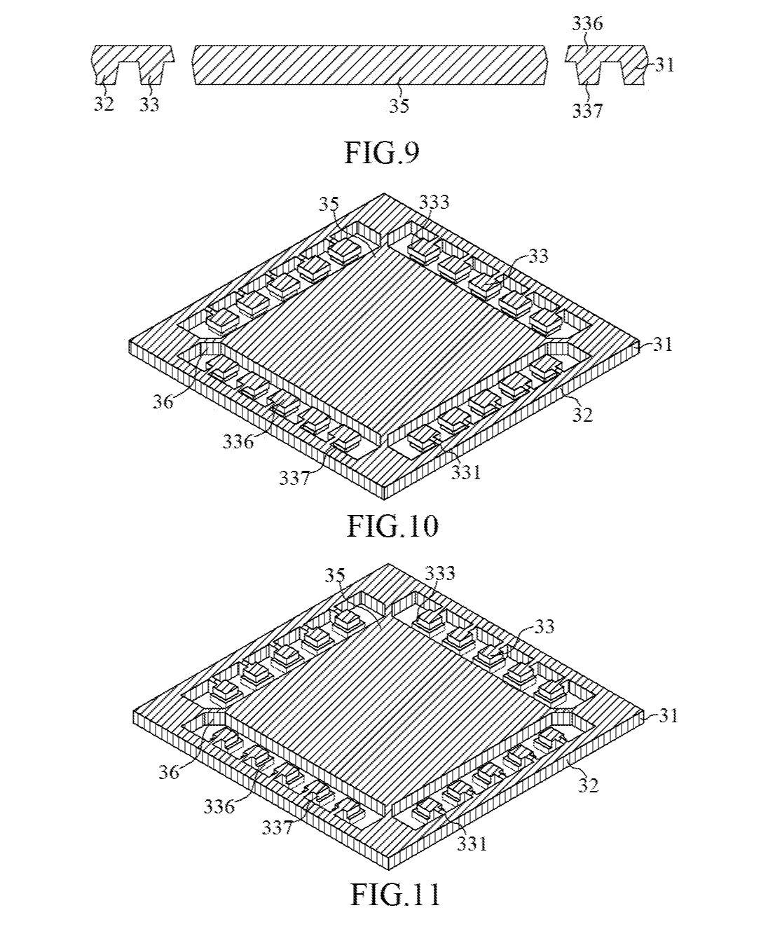

FIGS. 9, 10 and 11 are cross-sectional, top and bottom perspective views, respectively, of a textured metal sheet 31. The textured metal sheet 31 typically is made of copper alloys, steel or alloy 42, and can be formed by a wet etching or stamping/punching process from a rolled metal strip having a thickness in a range from about 0.15 mm to about 1.0 mm. The etching process may be a one-sided or two-sided etching to etch through the metal strip and thereby transfer the metal strip into a desired overall pattern of the textured metal sheet 31 that includes a metal frame 32, a plurality of metal leads 33, a sacrificial block 35 and a plurality of tie bars 36. The metal leads 33 laterally extend from the metal frame 32 toward the central area within the metal frame 32. As a result, the metal leads 33 each have an outer end 331 integrally connected to interior sidewalls of the metal frame 32 and an inner end 333 directed inwardly away from the metal frame 32. The sacrificial block 35 is located at the central area within the metal frame 32 and connected to the metal frame 32 by the tie bars 36. Additionally, in this embodiment, the textured metal sheet 31 is further selectively half-etched from its bottom side. Accordingly, the metal leads 33 have stepped peripheral edges. The metal leads 33 each have a horizontally elongated portion 336 and a vertically projected portion 337. The vertically projected portion 337 protrudes from a lower surface of the horizontally elongated portion 336 in the downward direction.

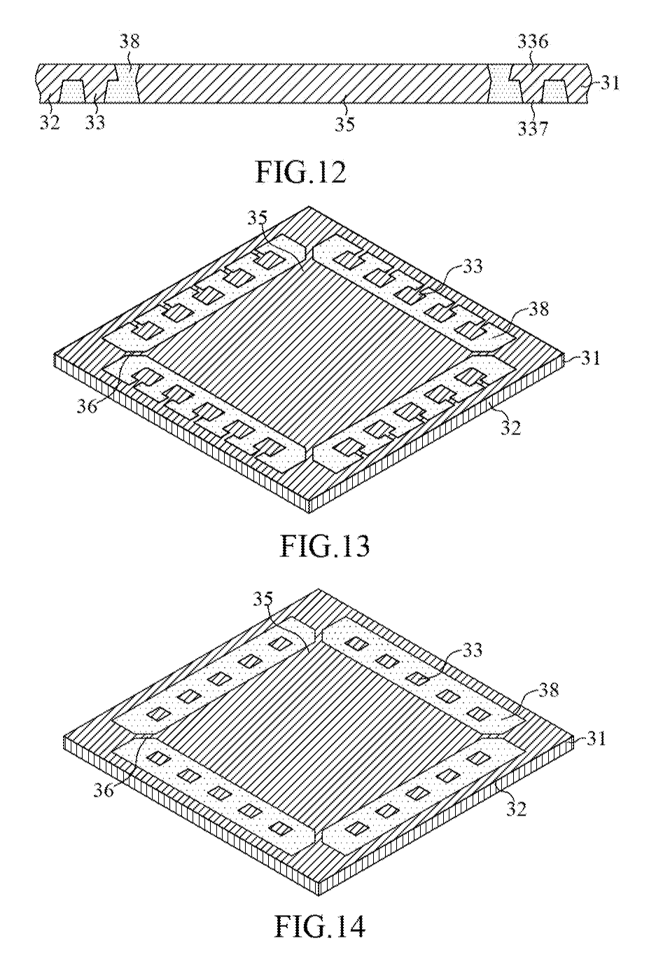

FIGS. 12, 13 and 14 are cross-sectional, top and bottom perspective views, respectively, of the structure provided with a first binding resin 38. The first binding resin 38 can be deposited by applying a resin material into the remaining spaces within the metal frame 32 to fill in spaces between the metal leads 33 and between the sacrificial block 35 and the metal leads 33. The resin material can be applied by paste printing, compressive molding, transfer molding, liquid injection molding, spin coating, or other suitable methods. Then, a thermal process (or heat-hardened process) is applied to harden the resin material and to transform it into a solid molding compound. As a result, the first binding resin 38 covers the lower surfaces of the horizontally elongated portions 336 as well as sidewalls of the vertically projected portions 337 and sidewalls of the sacrificial block 35. By the stepped cross-section profile of the metal leads 33, the first binding resin 38 can securely interlock with the metal leads 33 so as to prevent the metal leads 33 from being vertically forced apart from the first binding resin 38 and also to avoid micro-cracking at the interface along the vertical direction. In this illustration, the top surface of the first binding resin 38 is substantially coplanar with the top sides of the metal leads 33 and the sacrificial block 35, whereas the bottom surface of the first binding resin 38 is substantially coplanar with the bottom sides of the metal leads 33 and the sacrificial block 35 by planarization.

The first binding resin 38 typically includes binder resins, fillers, hardeners, diluents, and additives. There is no particular limit to the binder resin that can be used in accordance with the present invention. For example, the binder resin may be at least one selected from the group consisting of an epoxy resin, a phenol resin, a polyimide resin, a polyurethane resin, a silicone resin, a polyester resin, an acrylate, bismaleimide (BMI), and equivalents thereof. The binder resin provides intimate adhesion between an adherent and the filler. The binder resin also serves to elicit thermal conductivity through chain-like connection of the filler. The binder resin may also improve physical and chemical stability of the molding compound.

Additionally, there is no particular limit to the filler that can be used in accordance with the present invention. For example, a thermally conductive filler may be selected from the group consisting of aluminum oxide, aluminum nitride, silicon carbide, tungsten carbide, boron carbide, silica and equivalents thereof. More specifically, the first binding resin 38 may become thermally conductive or have low CTE if suitable fillers are dispersed therein. For example, aluminum nitride (AlN) or silicon carbide (SiC) has relatively high thermal conductivity, high electrical resistance, and a relatively low coefficient of thermal expansion (CTE). Accordingly, when the first binding resin 38 employs these kinds of materials as fillers, the first binding resin 38 would exhibit improved heat dissipation performance, electrical isolation performance and show inhibition of delamination or cracking of circuitry or interfaces due to low CTE. The maximum particle size of the thermally conductive filler may be 25 μm or less. The content of the filler may be in the range of 10 to 90% by weight. If the content of the thermally conductive filler is less than 10% by weight, this may result in insufficient thermal conductivity and excessively low viscosity. Low viscosity means that it may be difficult to handle and control the process due to excessively easy outflow of the resin from the tool during dispensing or molding process. On the other hand, if the content of the filler is higher than 90% by weight, this may result in decreased adhesive strength and excessively high viscosity of the molding material. High viscosity of the molding material results in poor workability due to no outflow of the material from the tool during the dispensing or molding process. Additionally, the first binding resin 38 may include more than one type of fillers. For example, the second filler may be polytetrafluoroethylene (PTFE) so as to further improve electrical isolation property of the first binding resin 38. In any case, the first binding resin 38 preferably has an elastic modulus larger than 1.0 GPa and a linear coefficient of thermal expansion in a range from about 5×10⁻⁶ K⁻¹ to about 15×10⁻⁶ K⁻¹.

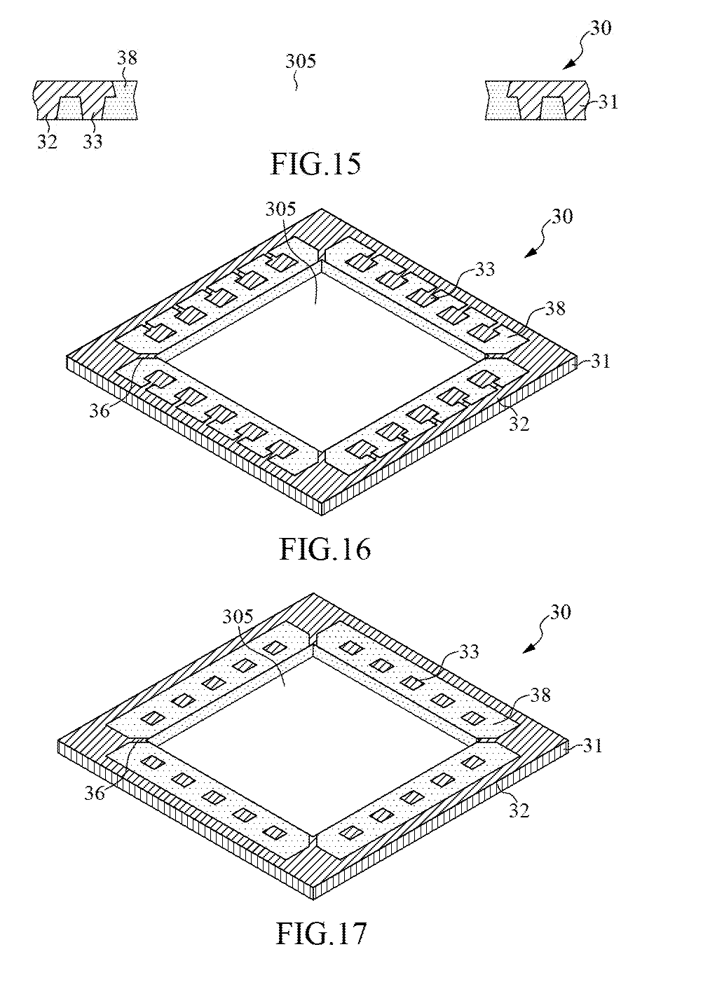

FIGS. 15, 16 and 17 are cross-sectional, top and bottom perspective views, respectively, of the structure after removal of the sacrificial block 35. The sacrificial block 35 can be entirely removed by numerous techniques, such as wet chemical etching, electro-chemical etching or laser, to form an aperture 305 that extends from the top surface to the bottom surface of the first binding resin 38. In this illustration, the interior sidewall surface of the first binding resin 38 defines an area with the same or similar topography as a subsequently disposed subcomponent. At this stage, an untrimmed leadframe 30 is accomplished and includes the metal frame 32, the metal leads 33, the tie bars 36 and the first binding resin 38.

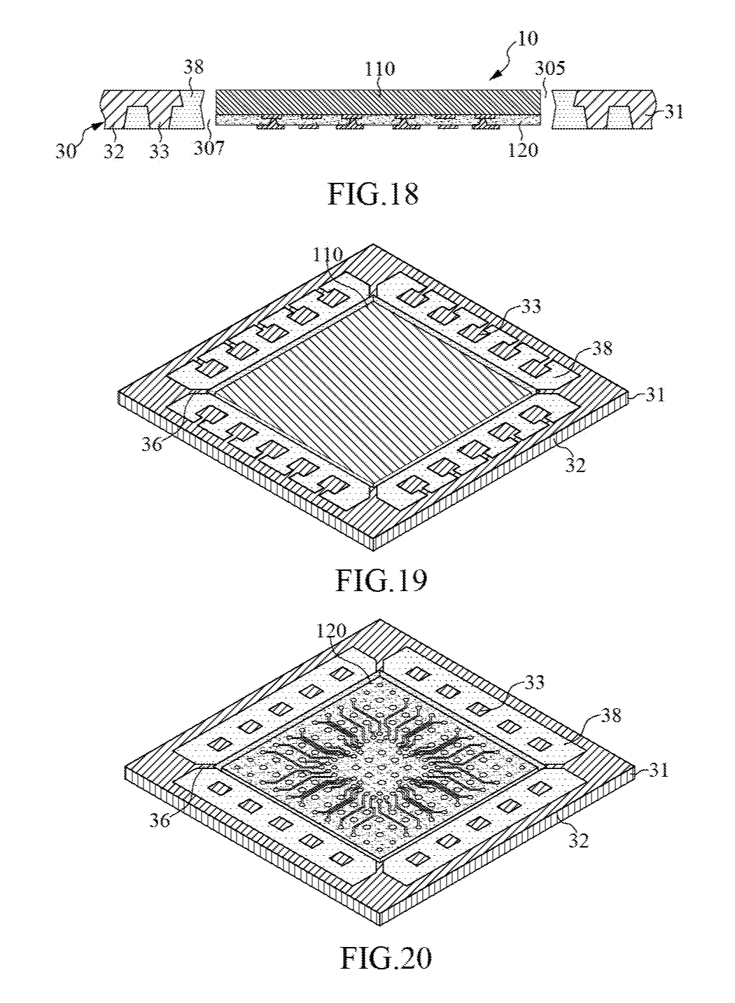

FIGS. 18, 19 and 20 are cross-sectional, top and bottom perspective views, respectively, of the structure with the subcomponent 10 inserted into the aperture 305 of the leadframe 30. Accordingly, the leadframe 30 laterally surrounds peripheral edges of the sacrificial carrier 110 and the first routing circuitry 120. In this illustration, the interior sidewall surface of the first binding resin 38 is spaced from and laterally aligned with and in close proximity to the peripheral edges of the subcomponent 10. As a result, the interior sidewall surface of the first binding resin 38 can prevent the lateral displacement of the subcomponent 10, and a space 307 is located in the aperture 305 between the subcomponent 10 and the leadframe 30. The space 307 is laterally surrounded by the leadframe 30, and laterally surrounds the subcomponent 10.

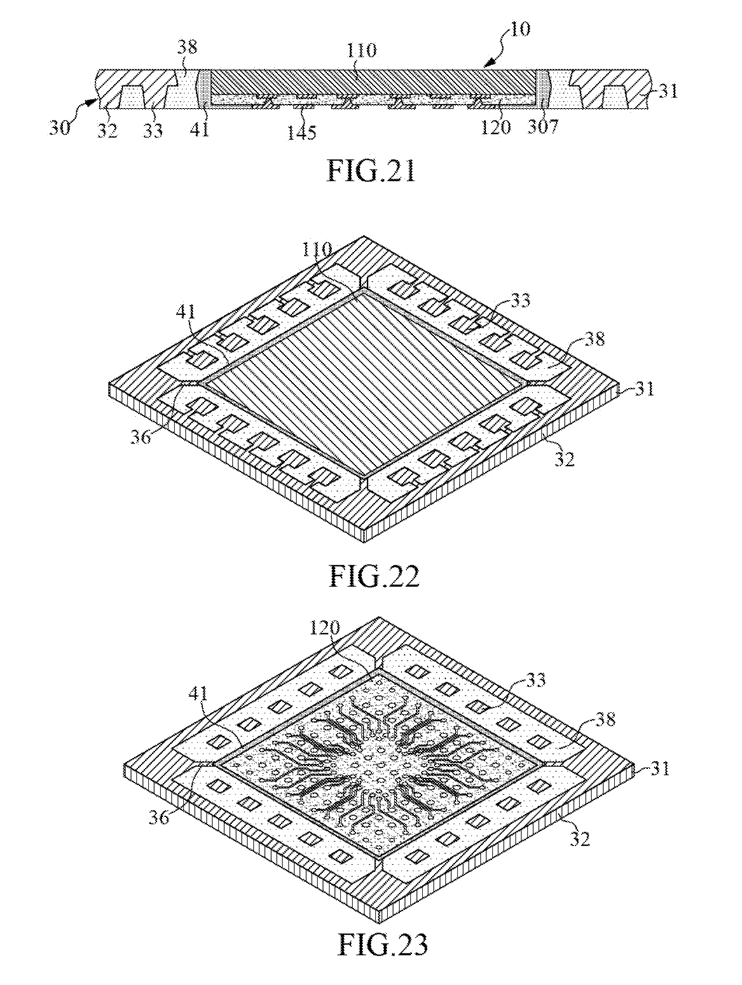

FIGS. 21, 22 and 23 are cross-sectional, top and bottom perspective views, respectively, of the structure provided with a second binding resin 41. The second binding resin 41 can be deposited by applying a resin material into the space 307 between the subcomponent 10 and the leadframe 30. The resin material can be applied by paste printing, compressive molding, transfer molding, liquid injection molding, spin coating, or other suitable methods. Then, a thermal process (or heat-hardened process) is applied to harden the resin material and to transform it into a solid molding compound. As a result, the second binding resin 41 coats peripheral edges of the sacrificial carrier 110 and the first routing circuitry 120 and interior sidewalls of the first binding resin 38. In this illustration, the top surface of the second binding resin 41 is substantially coplanar with the top surface of the first binding resin 38 and the exterior surface of the sacrificial carrier 110 as well as the top sides of the metal leads 33, whereas the bottom surface of the second binding resin 41 is substantially coplanar with the bottom surface of the first binding resin 38 and the exterior surface of the wiring layer 145 as well as the bottom sides of the metal leads 33 by planarization.

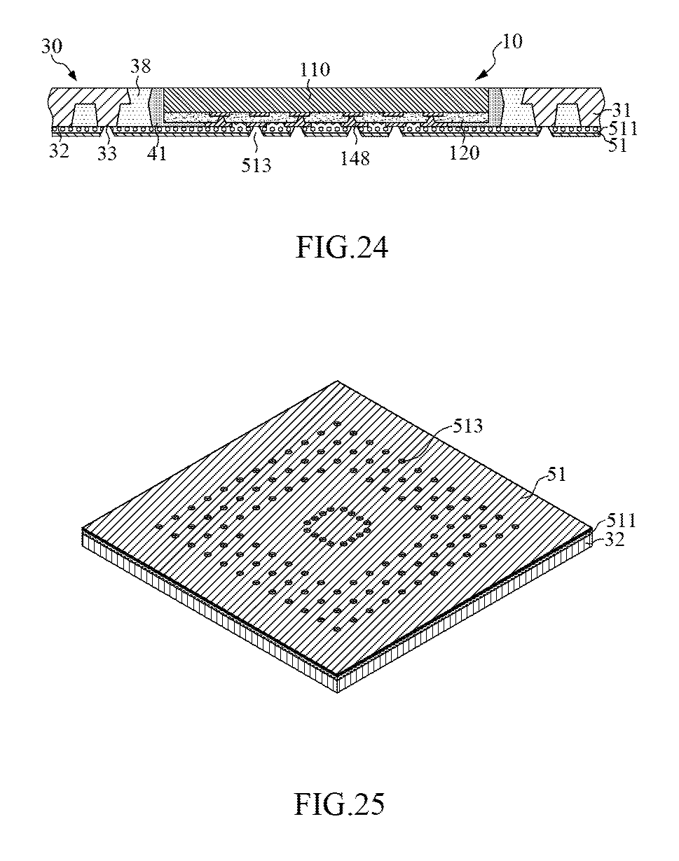

FIGS. 24 and 25 are cross-sectional and bottom perspective views, respectively, of the structure with a first dielectric layer 511 and a metal layer 51 laminated/coated on the subcomponent 10 and the leadframe 30 from below and via openings 513 formed in the first dielectric layer 511 as well as the metal layer 51. The first dielectric layer 511 contacts and is sandwiched between the metal layer 51 and the first routing circuitry 120, between the metal layer 51 and the leadframe 30, and between the metal layer 51 and the second binding resin 41. The dielectric layer 511 can be formed of epoxy resin, glass-epoxy, polyimide and the like, and typically has a thickness of 50 microns. The metal layer 51 typically is a copper layer with a thickness of 25 microns. The via openings 513 extend through the metal layer 51 and the first dielectric layer 511, and are aligned with the second electrical conductors 148 of the first routing circuitry 120 and the metal leads 33. The via openings 513 can be formed by any of numerous techniques including laser drilling, plasma etching and photolithography and typically have a diameter of 50 microns.

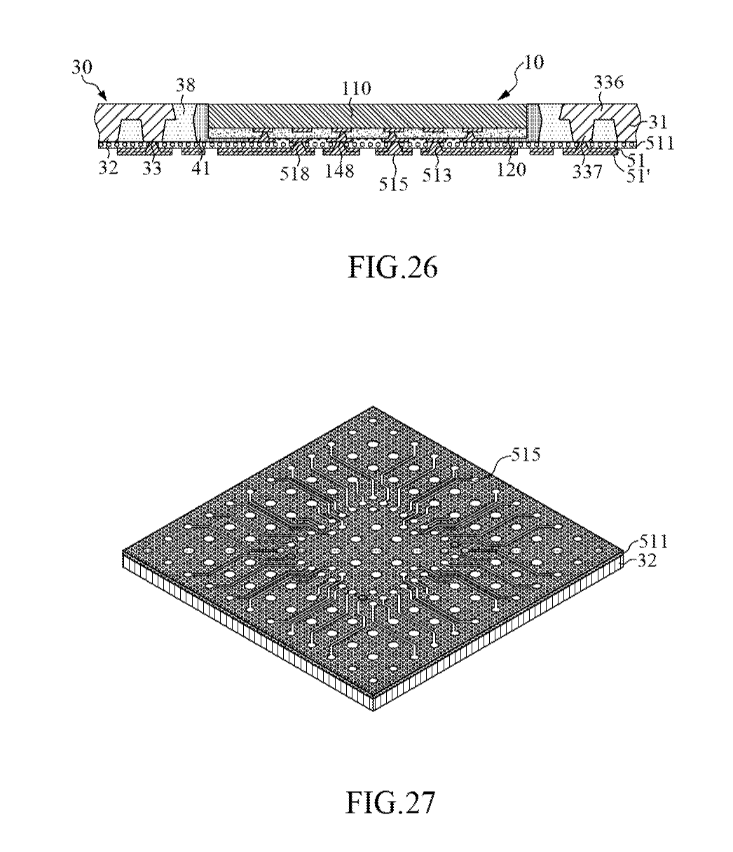

FIGS. 26 and 27 are cross-sectional and bottom perspective views, respectively, of the structure with a first wiring layer 515 formed on the first dielectric layer 511 by depositing a plated layer 51′ on the metal layer 51 and into the via openings 513 and then patterning the metal layer 51 as well as the plated layers 51′ thereon. The first wiring layer 515 extends from the second electrical conductors 148 of the first routing circuitry 120 and the vertically projected portions 337 of the metal leads 33 in the downward direction, fills up the via openings 513 to form metallized vias 518 in direct contact with the second electrical conductors 148 and the metal leads 33, and extends laterally on the first dielectric layer 511.

The metal layer 51 and the plated layer 51′ are shown as a single layer for convenience of illustration. The boundary (shown in broken lines) between the metal layers may be difficult or impossible to detect since copper is plated on copper.

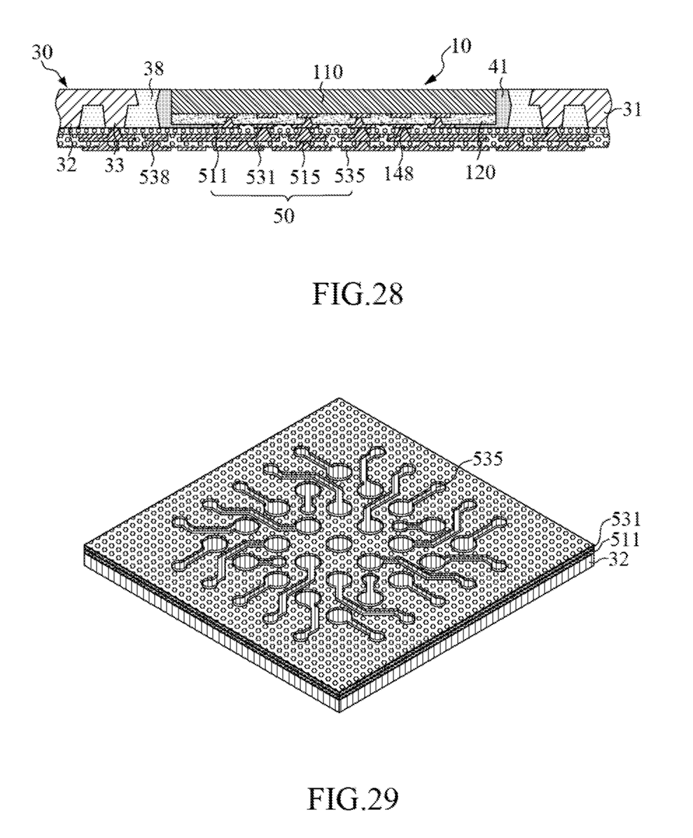

FIGS. 28 and 29 are cross-sectional and bottom perspective views, respectively, of the structure with a second dielectric layer 531 and a second wiring layer 535 serially formed in an alternate fashion. The second dielectric layer 531 covers the first dielectric layer 511 and the first wiring layer 515 from below. The second wiring layer 535 extends laterally on the second dielectric layer 531 and includes metallized vias 538 in direct contact with the first wiring layer 515.

At this stage, a second routing circuitry 50 is formed on the first routing circuitry 120 and the leadframe 30. In this illustration, the second routing circuitry 50 is a multi-layered buildup circuitry and includes the first dielectric layer 511, the first wiring layer 515, the second dielectric layer 531 and the second wiring layer 535.

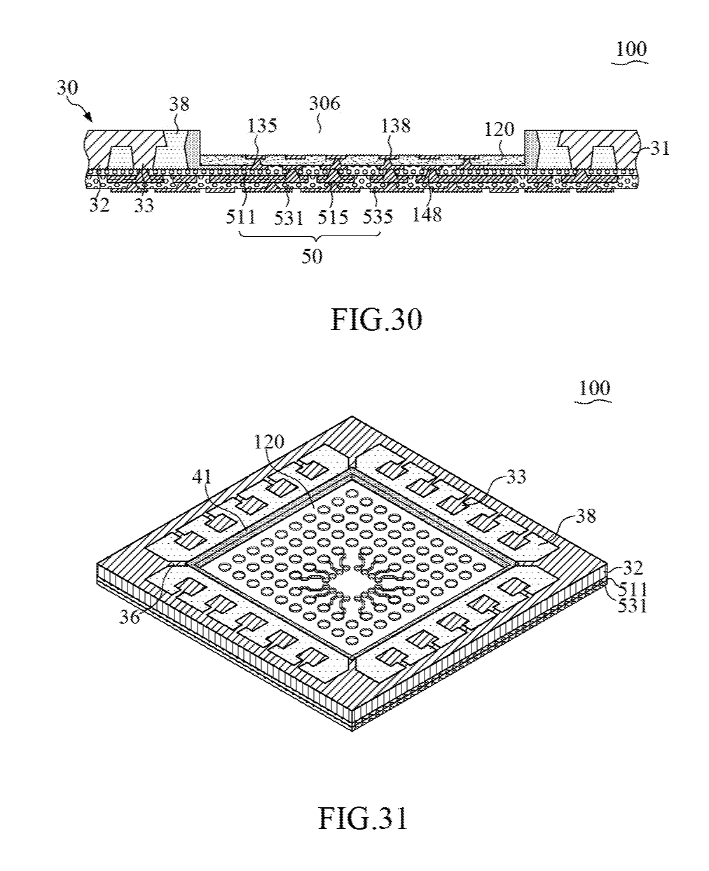

FIGS. 30 and 31 are cross-sectional and top perspective views, respectively, of the structure after removal of the sacrificial carrier 110. The sacrificial carrier 110 is removed to expose the first electrical conductors 138 of the first routing circuitry 120 from above. The sacrificial carrier 110 can be removed by numerous techniques including wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 110 made of an iron-based material is removed by a chemical etching solution that is selective between copper and iron so as to prevent the copper routing layer 135 from being etched during removal of the sacrificial carrier 110. Accordingly, an untrimmed wiring board 100 having a cavity 306 is accomplished and includes the first routing circuitry 120, the leadframe 30, the second binding resin 41 and the second routing circuitry 50.

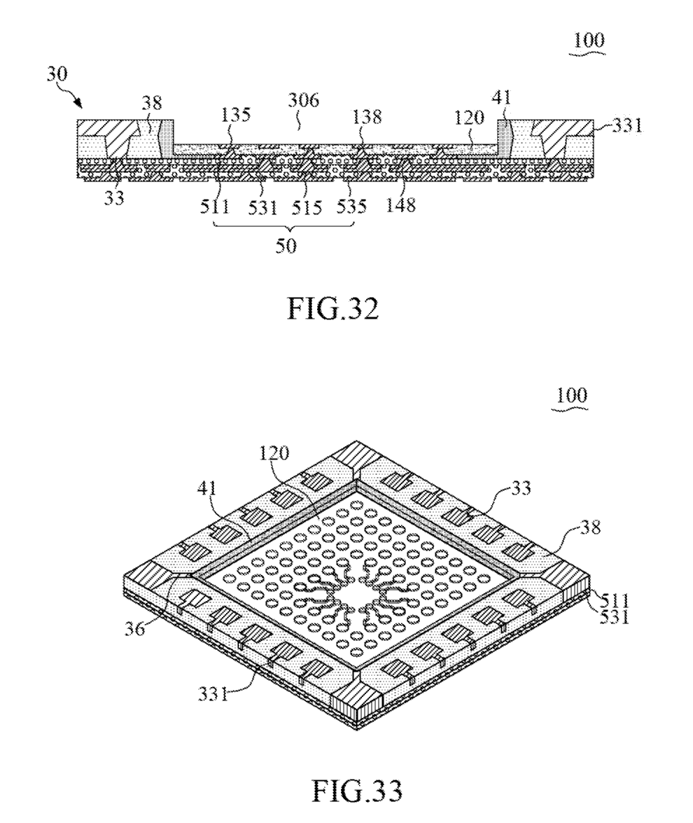

FIGS. 32 and 33 are cross-sectional and top perspective views, respectively, of the trimmed wiring board 100 after removal of the metal frame 32 as well as portions of the second routing circuitry 50. After separating the metal frame 32 from the metal leads 33, the outer ends 331 of the metal leads 33 are situated at peripheral edges of the trimmed wiring substrate 100 and have a lateral surface flush with peripheral edges of the first binding resin 38. At this stage, the trimmed leadframe 30 includes the metal leads 33, the tie bars 36 and the first binding resin 38.

### Embodiment 2

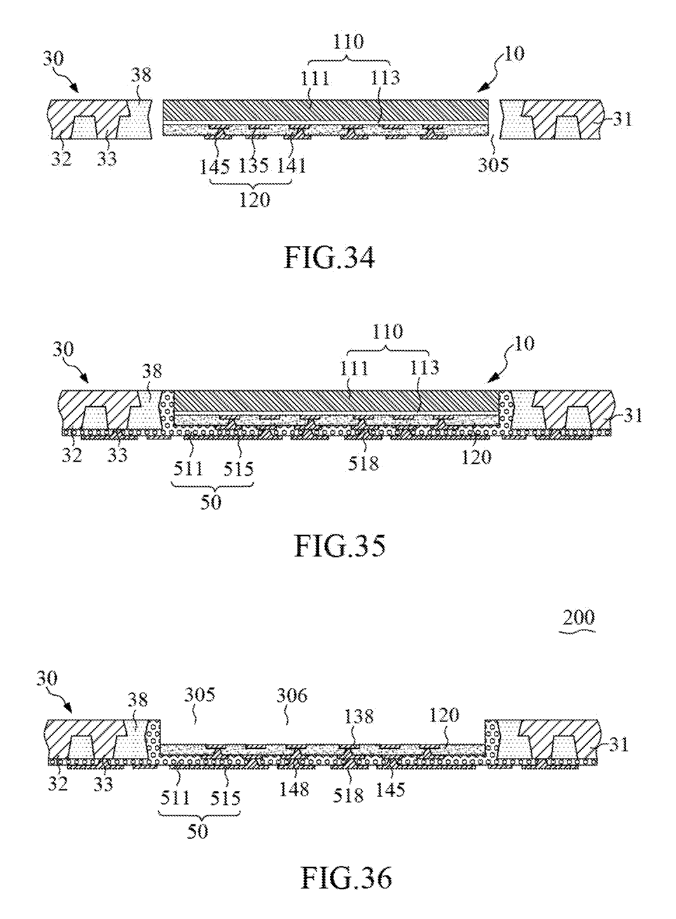

FIGS. 34-36 are schematic views showing a method of making another wiring board without the second binding resin in accordance with the second embodiment of the present invention.

For purposes of brevity, any description in Embodiment 1 above is incorporated herein insofar as the same is applicable, and the same description need not be repeated.

FIG. 34 is a cross-sectional view of the structure with a subcomponent 10 inserted into an aperture 305 of the leadframe 30 of FIG. 15. The subcomponent 10 is similar to that illustrated in FIG. 7, except that the sacrificial carrier 110 is a double-layer structure in this embodiment. The sacrificial carrier 110 includes a support sheet 111 and a barrier layer 113 deposited on the support sheet 111, and the first routing circuitry 120 is formed on the barrier layer 113. The barrier layer 113 can have a thickness of 0.001 to 0.1 mm, and may be a metal layer that is inactive against chemical etching during chemically removing the support sheet 111 and can be removed without affecting the routing layer 135. For instance, the barrier layer 113 may be made of tin or nickel when the support sheet 111 and the routing layer 135 are made of copper. Further, in addition to metal materials, the barrier layer 113 can also be a dielectric layer such as a peelable laminate film. In this embodiment, the support sheet 111 is a copper sheet, and the barrier layer 113 is a nickel layer of 3 microns in thickness.

FIG. 35 is a cross-sectional view of the structure with a second routing circuitry 50 on the first routing circuitry 120 and the leadframe 30. In this illustration, the second routing circuitry 50 includes a first dielectric layer 511 and a first wiring layer 515 serially formed in an alternate fashion. The first dielectric layer 511 covers and contacts the first routing circuitry 120, the metal leads 33 and the first binding resin 38 from below, and further extends into a space between the sacrificial carrier 110 and the first binding resin 38 and between the first routing circuitry 120 and the first binding resin 38. In this illustration, the portion of the first dielectric layer 511 in the space between the subcomponent 10 and the first binding resin 38 has a top surface substantially coplanar with the top sides of the metal leads 33 and the top surface of the first binding resin 38. The first wiring layer 515 is electrically coupled to the first routing circuitry 120 and the metal leads 33 through metallized vias 518.

FIG. 36 is a cross-sectional view of the structure after removal of the sacrificial carrier 110. The support sheet 111 made of copper is removed by an alkaline etching solution. Subsequently, the barrier layer 113 made of nickel is removed by an acidic etching solution to expose the first electrical conductors 138 of the first routing circuitry 120 from the cavity 306. In another aspect of the barrier layer 113 being a peelable laminate film, the barrier layer 113 can be removed by mechanical peeling or plasma ashing. Accordingly, an untrimmed wiring board 200 is accomplished and includes the first routing circuitry 120, the leadframe 30 and the second routing circuitry 50.

The first routing circuitry 120 is positioned within the aperture 305 of the leadframe 30, and the second routing circuitry 50 is positioned beyond the aperture 305 of the leadframe 30 and laterally extends to peripheral edges of the wiring board 200. As such, the first routing circuitry 120 has a smaller exposed surface area than that of the second routing circuitry 50.

The leadframe 30 laterally surrounds peripheral edges of the first routing circuitry 120 and laterally extends to the peripheral edges of the wiring board 200, and can provide mechanical support and suppress warping and bending of the wiring board 200. Further, the leadframe 30 extends beyond the exposed surface of the first routing circuitry 120 in the upward direction, and the bottom surface of the leadframe 30 is substantially coplanar with the exterior surface of the wiring layer 145 of the first routing circuitry 120 in the downward direction.

The second routing circuitry 50 includes the first wiring layer 515 extending into an area outside of the aperture 305 of the leadframe 30 and laterally extending over the bottom surface of the leadframe 30, and is electrically coupled to the second electrical conductors 148 of the first routing circuitry 120 and the metal leads 33 of the leadframe 30 through the metallized vias 518 of the second routing circuitry 50. Further, the first dielectric layer 511 of the second routing circuitry 50 further extends into the space between the first routing circuitry 120 and the leadframe 30 and laterally surrounds the cavity 306. As such, the second routing circuitry 50 not only provides further fan-out wiring structure for the first routing circuitry 120, but also mechanically binds the first routing circuitry 120 with the leadframe 30.

### Embodiment 3

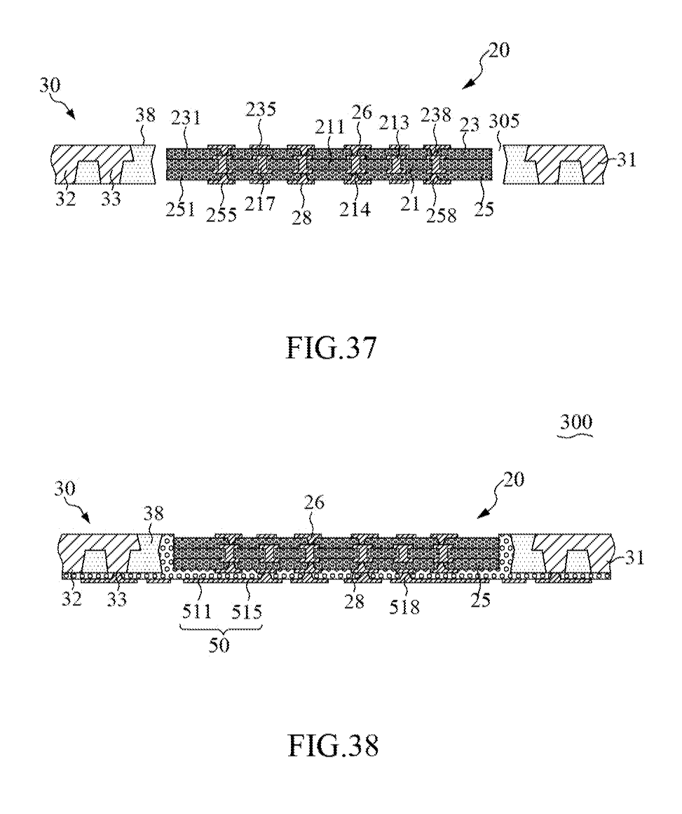

FIGS. 37-38 are schematic views showing a method of making yet another wiring board without a cavity in accordance with the third embodiment of the present invention.

For purposes of brevity, any description in the Embodiments above is incorporated herein insofar as the same is applicable, and the same description need not be repeated.

FIG. 37 is a cross-sectional view of the structure with a first routing circuitry 20 inserted into an aperture 305 of the leadframe 30 of FIG. 15. In this illustration, the first routing circuitry 20 has a thickness substantially equal to that of the leadframe 30 and includes an interconnect substrate 21, a first buildup circuitry 23 and a second buildup circuitry 25. The interconnect substrate 21 includes a core layer 211, a first routing layer 213, a second routing layer 214 and metallized through vias 217. The first routing layer 213 and the second routing layer 214 respectively extend laterally on both sides of the core layer 211, and metallized through vias 217 extend through the core layer 211 to provide electrical connections between the first routing layer 213 and the second routing layer 214. The first buildup circuitry 23 and the second buildup circuitry 25 are respectively disposed on both sides of the interconnect substrate 21, and each of them includes a dielectric layer 231, 251 and conductive traces 233, 253. The dielectric layers 231, 251 respectively cover both sides of the interconnect substrate 21 from below and above, and can be made of epoxy resin, glass-epoxy, polyimide, or the like. The conductive traces 235, 255 respectively extend laterally on the dielectric layers 231, 251, and include metallized vias 238, 258 in the dielectric layers 231, 251. The metallized vias 238, 258 contact the first and second routing layers 213, 214 of the interconnect substrate 21, and extend through the dielectric layers 231, 251. As a result, the first routing circuitry 20 includes first electrical conductors 26 for device connection and second electrical conductors 28 for next-level circuitry connection.

FIG. 38 is a cross-sectional view of the structure with a second routing circuitry 50 on the first routing circuitry 20 and the leadframe 30. In this illustration, the second routing circuitry 50 includes a first dielectric layer 511 and a first wiring layer 515 serially formed in an alternate fashion. The first dielectric layer 511 covers and contacts the first routing circuitry 20 and the leadframe 30 from below, and further extends into a space between the first routing circuitry 20 and the first binding resin 38. The first wiring layer 515 is electrically coupled to the second buildup circuitry 25 of the first routing circuitry 20 and the metal leads 33 through metallized vias 518.

Accordingly, an untrimmed wiring board 300 is accomplished and includes the first routing circuitry 20, the leadframe 30 and the second routing circuitry 50.

### Embodiment 4

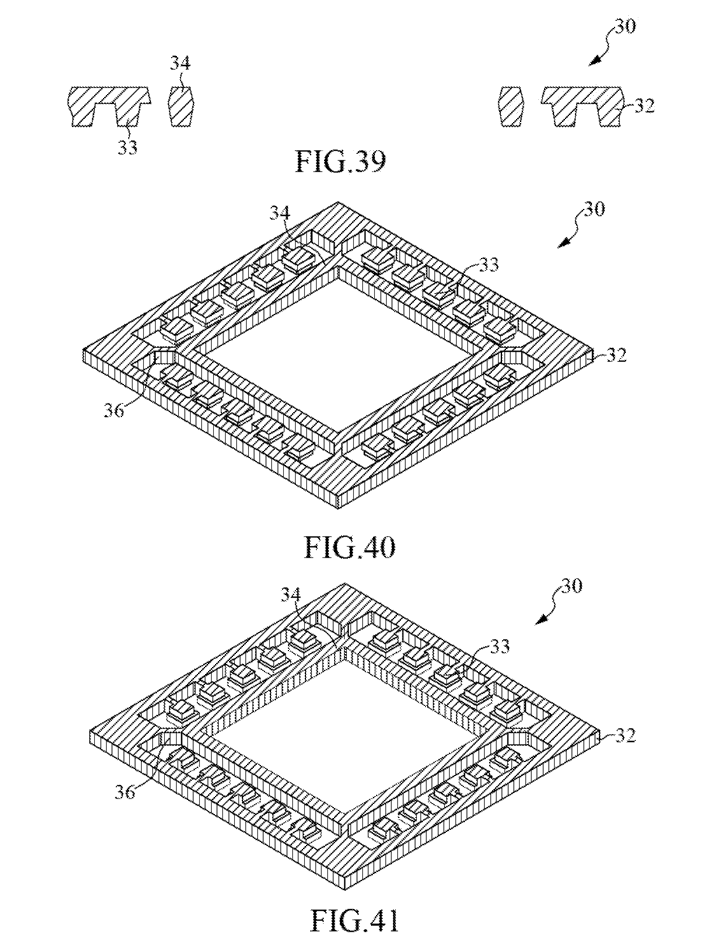

FIGS. 39-55 are schematic views showing a method of making yet another wiring board without the first binding resin and the second binding resin in accordance with the fourth embodiment of the present invention.

For purposes of brevity, any description in the Embodiments above is incorporated herein insofar as the same is applicable, and the same description need not be repeated.

FIGS. 39, 40 and 41 are cross-sectional, top and bottom perspective views, respectively, of a leadframe 30. In this illustration, the leadframe 30 includes a metal frame 32, a plurality of metal leads 33, a metal alignment guide 34 and a plurality of tie bars 36. The metal leads 33 are integrally connected to the metal frame 32 and located between the metal alignment guide 34 and the metal frame 32. The metal alignment guide 34 are connected to the metal frame 32 by the tie bars 36 and defines an area with the same or similar topography as a subsequently disposed subcomponent. Additionally, in this embodiment, the metal leads 33 are further selectively half-etched from their bottom sides. Accordingly, the metal leads 33 have stepped peripheral edges.

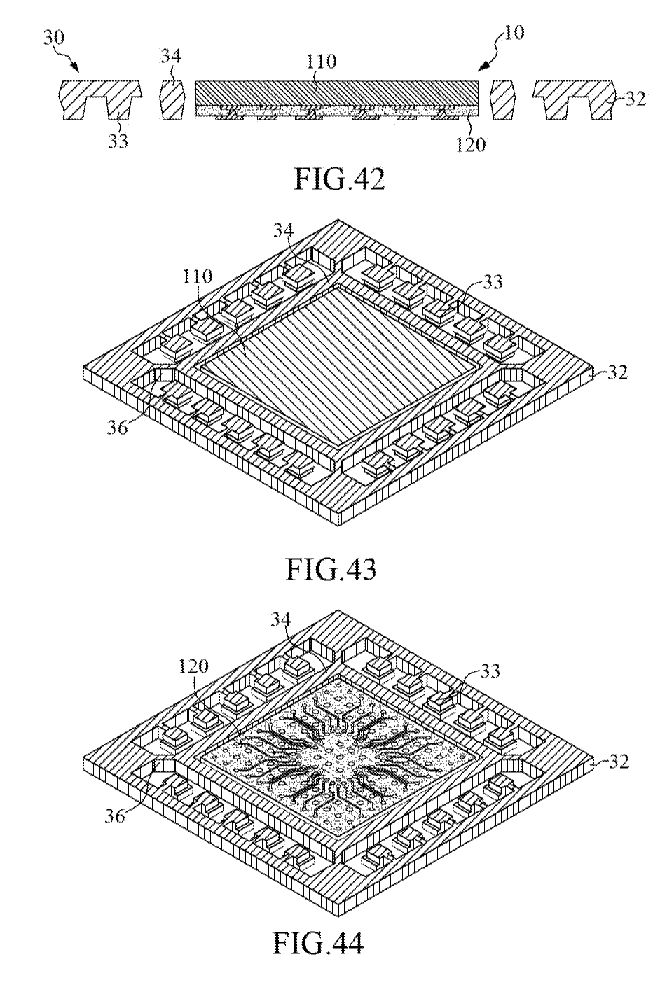

FIGS. 42, 43 and 44 are cross-sectional, top and bottom perspective views, respectively, of the structure with the subcomponent 10 of FIG. 7 placed in the area laterally surrounded by the metal alignment guide 34. The subcomponent placement accuracy is provided by the metal alignment guide 34 laterally aligned with and in close proximity to the peripheral edges of the subcomponent 10. As a result, the metal alignment guide 34 can prevent the lateral displacement of the subcomponent 10 and confine the subcomponent 10 at the predetermined location.

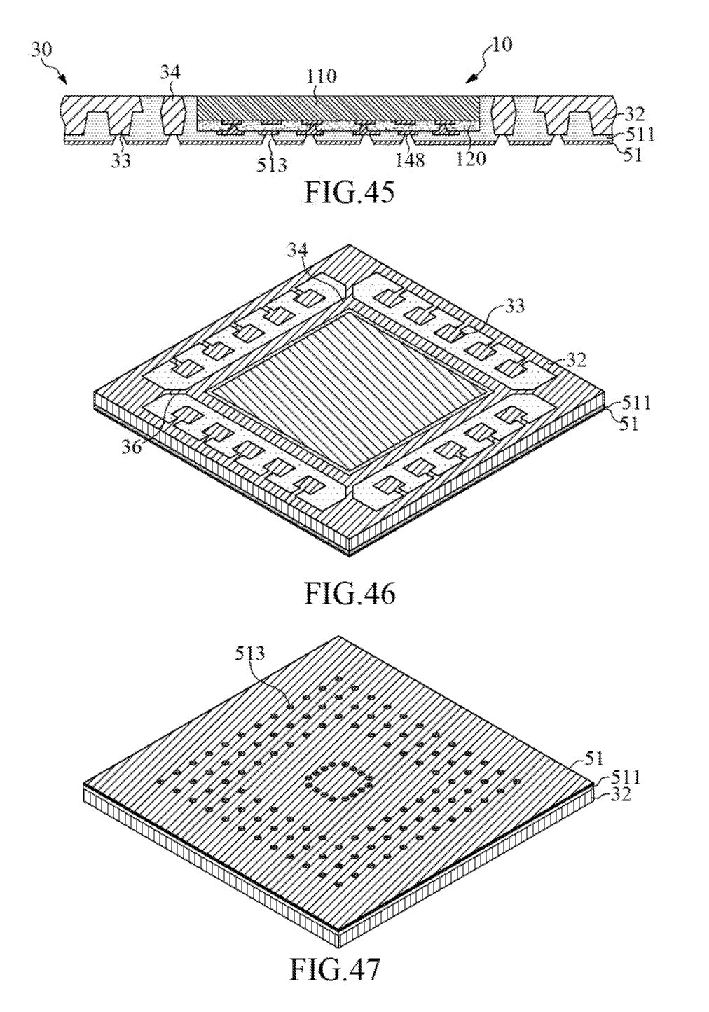

FIGS. 45, 46 and 47 are cross-sectional, top and bottom perspective views, respectively, of the structure with a first dielectric layer 511 and a metal layer 51 laminated/coated on the subcomponent 10 and the leadframe 30 from below and via openings 513 formed in the first dielectric layer 511 as well as the metal layer 51. The first dielectric layer 511 contacts and covers the first routing circuitry 120 and the leadframe 30 from below and further fills in spaces between the metal leads 33 and between the subcomponent 10 and the metal alignment guide 34. In this illustration, the portion of the first dielectric layer 511 in the spaces between the metal leads 33 and between the subcomponent 10 and the metal alignment guide 34 has a top surface substantially coplanar with the top sides of the metal leads 33 and the metal alignment guide 34. The metal layer 51 contacts and covers the first dielectric layer 511 from below. The via openings 513 extend through the metal layer 51 and the first dielectric layer 511, and are aligned with the second electrical conductors 148 of the first routing circuitry 120, the metal leads 33 and the metal alignment guide 34 to expose selected portions of the second electrical conductors 148, the metal leads 33 and the metal alignment guide 34 from below.

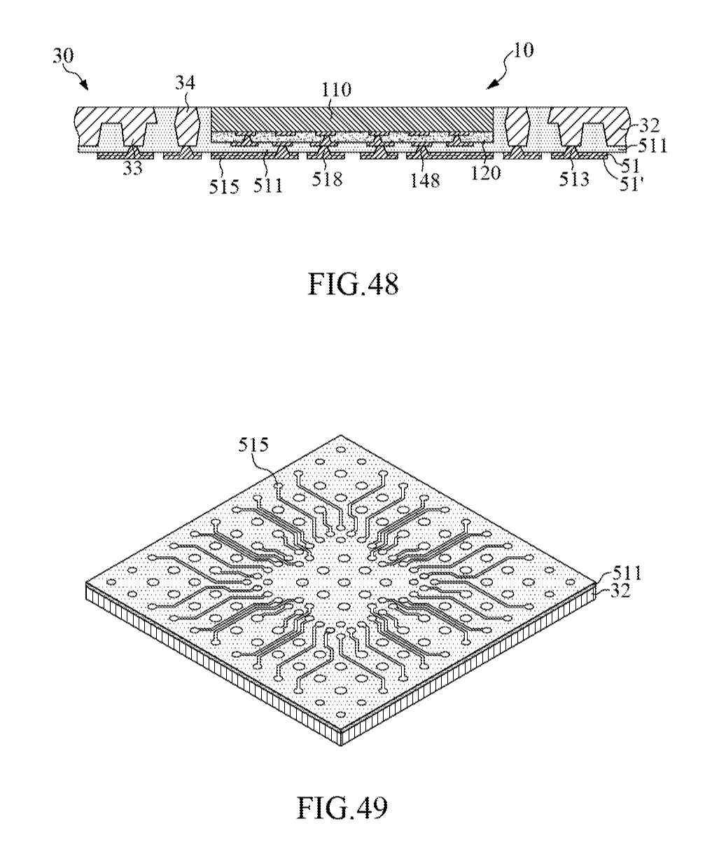

Referring now to FIGS. 48 and 49, a first wiring layer 515 is formed on the first dielectric layer 511 by depositing a plated layer 51′ on the metal layer 51 and into the via openings 513 and then patterning the metal layer 51 as well as the plated layers 51′ thereon. The first wiring layer 515 extends from the second electrical conductors 148, the metal leads 33 and the metal alignment guide 34 in the downward direction, fills up the via openings 513 to form metallized vias 518 in direct contact with the second electrical conductors 148, the metal leads 33 and the metal alignment guide 34, and extends laterally on the first dielectric layer 511.

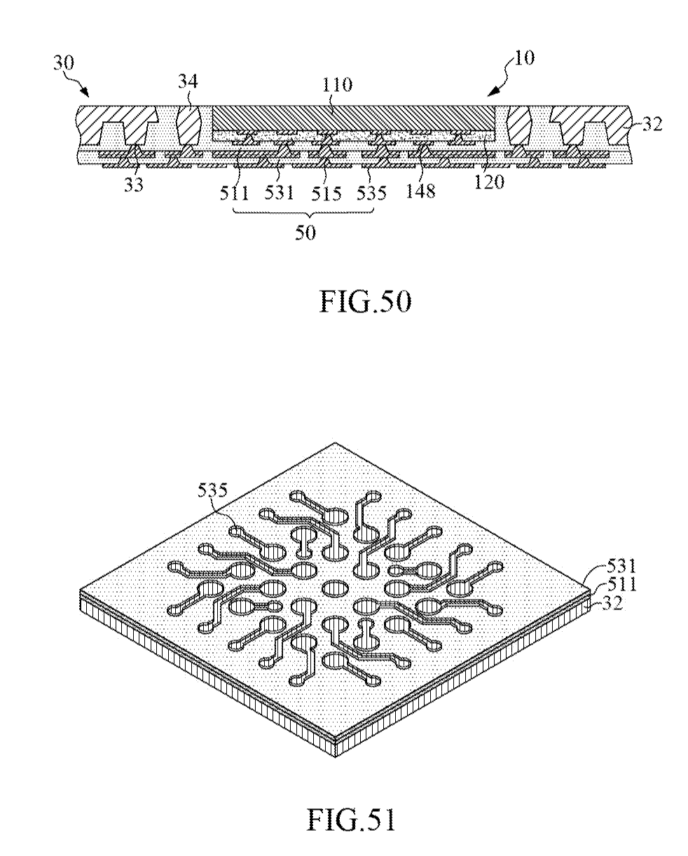

FIGS. 50 and 51 are cross-sectional and bottom perspective views, respectively, of the structure with a second dielectric layer 531 and a second wiring layer 535 serially formed in an alternate fashion. The second dielectric layer 531 covers the first dielectric layer 511 and the first wiring layer 515 from below. The second wiring layer 535 extends laterally on the second dielectric layer 531 and includes metallized vias 538 in direct contact with the first wiring layer 515.

At this stage, a second routing circuitry 50 is formed on the first routing circuitry 120 and the leadframe 30 and electrically connected to the first routing circuitry 120 and the metal leads 33 for signal routing and to the metal alignment guide 34 for ground connection. In this illustration, the second routing circuitry 50 is a multi-layered buildup circuitry and includes the first dielectric layer 511, the first wiring layer 515, the second dielectric layer 531 and the second wiring layer 535.

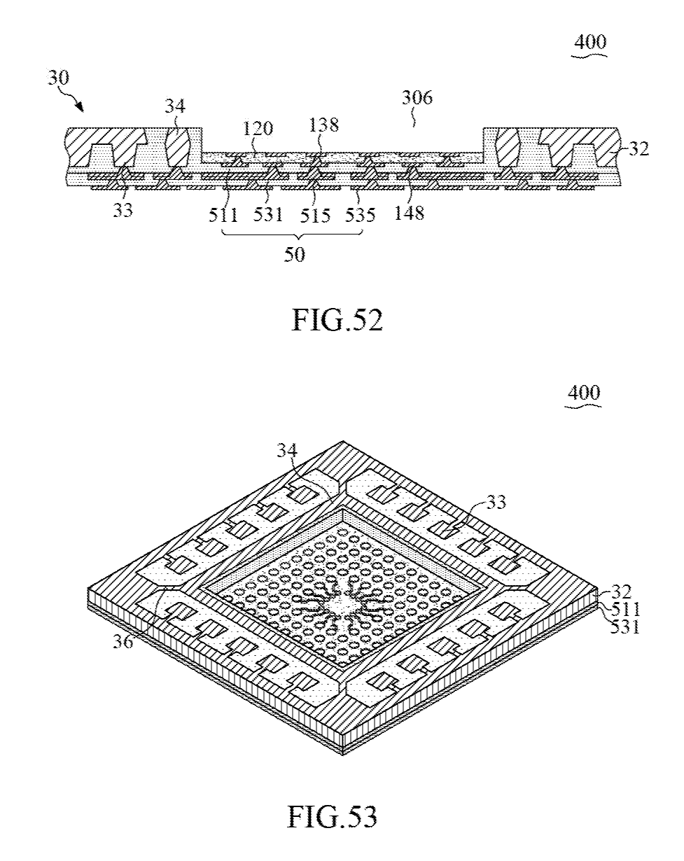

FIGS. 52 and 53 are cross-sectional and top perspective views, respectively, of the structure with the first electrical conductors 138 exposed from a cavity 306 after removal of the sacrificial carrier 110. Accordingly, an untrimmed wiring board 400 is accomplished and includes the first routing circuitry 120, the leadframe 30 and the second routing circuitry 50.

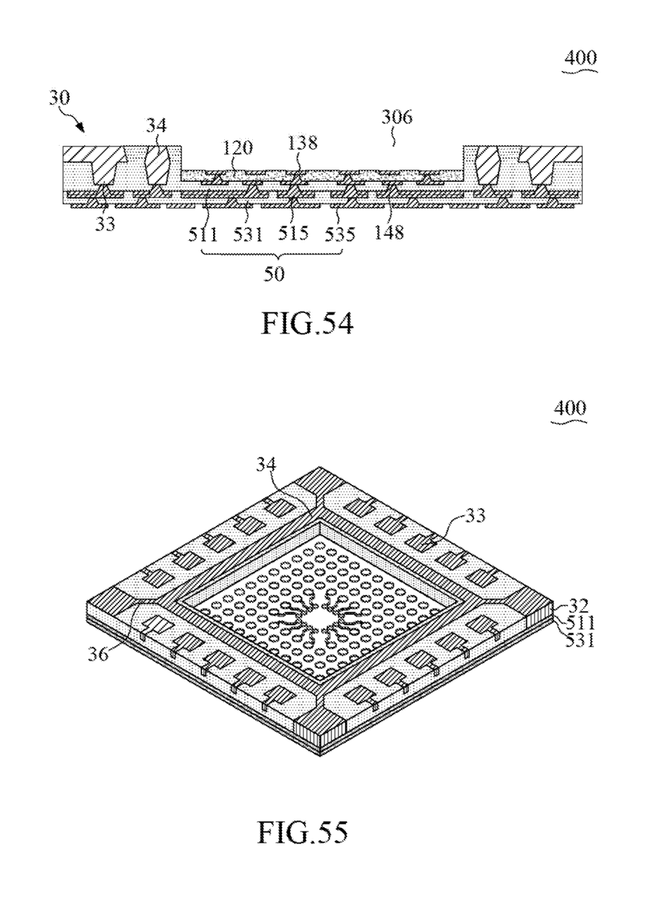

FIGS. 54 and 55 are cross-sectional and top perspective views, respectively, of the trimmed wiring board 400 after removal of the metal frame 32 as well as portions of the second routing circuitry 50. By separating the metal frame 32, the connection between the metal leads 33 is broken. As a result, the leadframe 30 includes the metal leads 33, the metal alignment guide 34 and the tie bars 36.

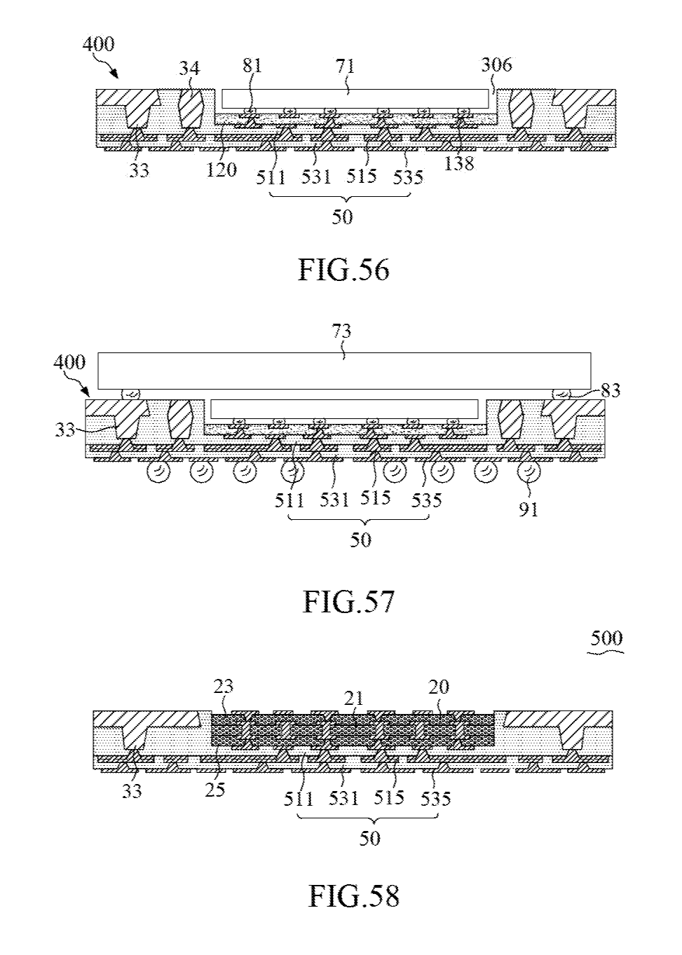

FIG. 56 is a cross-sectional view of a semiconductor assembly with a first semiconductor device 71, illustrated as a chip, mounted on the wiring board 400 illustrated in FIG. 54. The first semiconductor device 71 is positioned within the cavity 306 and is flip-chip mounted on the first electrical conductors 138 of the first routing circuitry 120 via solder bumps 81.

FIG. 57 is a cross-sectional view of the semiconductor assembly of FIG. 56 further provided with solder balls 91 and a second semiconductor device 73 mounted on the opposite sides of the wiring board 400, respectively. The solder balls 91 are mounted on the second wiring layer 535 of the second routing circuitry 50 for next-level connection. The second semiconductor device 73 can be a ball grid array package or a bumped chip, and is electrically coupled to the wiring board 400 through a plurality of solder balls 83 in contact with the second semiconductor device 73 and the metal leads 33.

### Embodiment 5

FIG. 58 is a cross-sectional view of a wiring board in accordance with the fifth embodiment of the present invention.

For purposes of brevity, any description in the Embodiments above is incorporated herein insofar as the same is applicable, and the same description need not be repeated.

The semiconductor assembly 500 is similar to that illustrated in FIG. 54, except that (i) the first routing circuitry 20 has a thickness substantially equal to that of the leadframe 30 and includes an interconnect substrate 21, a first buildup circuitry 23 and a second buildup circuitry 25, and (ii) no metal alignment guide is located between the first routing circuitry 20 and the metal leads 33.

The wiring board and assemblies described above are merely exemplary. Numerous other embodiments are contemplated. In addition, the embodiments described above can be mixed-and-matched with one another and with other embodiments depending on design and reliability considerations. For instance, the wiring board may include multiple first routing circuitries arranged in an array. Also, the second routing circuitry can include additional conductive traces to receive and route additional second electrical conductors of additional first routing circuitries.

As illustrated in the aforementioned embodiments, a distinctive wiring board is configured to include a first routing circuitry laterally surrounded by metal leads and electrically coupled to a second routing circuitry. In accordance with one preferred embodiment of the present invention, the wiring board includes: a leadframe that includes a plurality of metal leads and a first binding resin, wherein the first binding resin fills in spaces between the metal leads and laterally surrounds a predetermined area; a first routing circuitry that is positioned within the predetermined area, wherein the first routing circuitry includes first electrical conductors and second electrical conductors at two opposite sides thereof, respectively, and the first electrical conductors are exposed from the predetermined area and electrically connected to the second electrical conductors; and a second routing circuitry that is disposed over the first routing circuitry and laterally extends over the leadframe, wherein the second routing circuitry includes at least one dielectric layer and at least one wiring layer in an alternate fashion, and the wiring layer of the second routing circuitry is electrically coupled to the second electrical conductors of the first routing circuitry and the metal leads. Optionally, the wiring board of the preferred embodiment may further include a second binding resin that fills into a space between the leadframe and the first routing circuitry. Alternatively, the dielectric layer of the second routing circuitry may further extend into the space between the leadframe and the first routing circuitry. In accordance with another preferred embodiment of the present invention, the wiring substrate includes: a leadframe that includes a plurality of metal leads, wherein each of the metal leads has an inner end directed toward a predetermined area and an outer end situated farther away from the predetermined area than the inner end; a first routing circuitry that is positioned within the predetermined area, wherein the first routing circuitry includes first electrical conductors and second electrical conductors at two opposite sides thereof, respectively, and the first electrical conductors are exposed from the predetermined area and electrically connected to the second electrical conductors; and a second routing circuitry that is disposed over the first routing circuitry and laterally extends over the leadframe, wherein the second routing circuitry includes at least one dielectric layer and at least one wiring layer in an alternate fashion, and a portion of the dielectric layer fills in spaces between the metal leads, and the wiring layer of the second routing circuitry is electrically coupled to the second electrical conductors of the first routing circuitry and the metal leads. Optionally, the leadframe may further include a metal alignment guide laterally aligned with the peripheral edges of the first routing circuitry, and a portion of the dielectric layer of the second routing circuitry may further fill in a space between the metal alignment guide and the peripheral edges of the first routing circuitry.

The leadframe is located around peripheral edges of the first routing circuitry. In a preferred embodiment, the leadframe is fabricated by steps of: providing a metal frame and metal leads integrally connected to the metal frame; and depositing a first binding resin that fills in remaining spaces within the metal frame. After forming the first binding resin, the metal frame can be separated from the metal leads. As a result, the metal leads can have an exterior lateral surface flush with peripheral edges of the first binding resin. Furthermore, a sacrificial block may be provided within the metal frame before provision of the first binding resin. Accordingly, by removing the sacrificial block after forming the first binding resin, an aperture can be formed in the leadframe. Specifically, the aperture of the leadframe is laterally surrounded by the first binding resin and extends from the top surface of the first binding resin to the bottom surface of the first binding resin. In a preferred embodiment, the interior sidewall surface of the aperture of the leadframe laterally surrounds and is spaced from and bonded to peripheral edges of the first routing circuitry by the second binding resin or the dielectric layer of the second routing circuitry. In order to confine the first routing circuitry at the predetermined location, the interior sidewall surface of the aperture of the leadframe preferably defines an area with the same or similar topography as the first routing circuitry. As a result, the placement accuracy for the first routing circuitry can be provided by the interior sidewall surface of the aperture of the leadframe preferably laterally aligned with in close proximity to the peripheral edges of the first routing circuitry. In an alternative aspect, the leadframe without first binding resin may be fabricated by steps of: providing a metal frame and metal leads, wherein the metal leads are integrally connected to the metal frame; and optionally providing a metal alignment guide within the metal frame. In this alternative aspect, the spaces between the metal leads are filled with a portion of the dielectric layer of the second routing circuitry, and the optional metal alignment guide can be laterally aligned with the peripheral edges of the first routing circuitry to provide placement accuracy for the first routing circuitry. After a portion of the dielectric layer of the second routing circuitry extends into the spaces between the metal leads, the metal frame can be separated from the metal leads.

The metal leads can serve as horizontal and vertical signal transduction pathways or provide ground/power plane for power delivery and return. Each of the metal leads preferably is an integral one-piece lead and can be separated from a metal frame after provision of the first binding resin or after a portion of the dielectric layer of the second routing circuitry fills in the spaces between the metal leads. The metal leads separated from the metal frame have top and bottom sides and an exterior lateral surface perpendicular to the top and bottom sides and not covered by the first binding resin or the dielectric layer of the second routing circuitry. The bottom sides of the metal leads preferably are substantially coplanar with the exterior surfaces of the second electrical conductors of the first routing circuitry. In a preferred embodiment, the metal leads have a thickness in a range from about 0.15 mm to about 1.0 mm and laterally extend at least to a perimeter coincident with peripheral edges of the first binding resin or the dielectric layer of the second routing circuitry. For secure bonds between the metal leads and the first binding resin or between the metal leads and the dielectric layer of the second routing circuitry, the metal leads may have stepped peripheral edges interlocked with the first binding resin or the dielectric layer of the second routing circuitry. As a result, the first binding resin or the dielectric layer of the second routing circuitry in the spaces between the metal leads also has a stepped cross-sectional profile where it contacts the metal leads so as to prevent the metal leads from being vertically forced apart from the first binding resin or the dielectric layer of the second routing circuitry and also to avoid micro-cracking at the interface along the vertical directions.

The first binding resin can provide mechanical bonds between the metal leads, and may have a top surface substantially coplanar with the top sides of the metal leads and a bottom surface substantially coplanar with the bottom sides of the metal leads. Further, the bottom surface of the first binding resin and the bottom sides of the metal leads preferably are substantially coplanar with the exterior surfaces of the second electrical conductors of the first routing circuitry. Preferably, the first binding resin has an elastic modulus larger than 1.0 GPa, a linear coefficient of thermal expansion in a range from about 5×10⁻⁶ K⁻¹ to about 15×10⁻⁶ K⁻¹. Additionally, for sufficient thermal conductivity and suitable viscosity, the first binding resin may include thermally conductive fillers in a range of 10 to 90% by weight. For instance, the thermally conductive fillers may be made of aluminum nitride (AlN), aluminum oxide, silicon carbide (SiC), tungsten carbide, boron carbide, silica or the like and preferably has relatively high thermal conductivity, high electrical resistance, and a relatively low CTE. Accordingly, the first binding resin would exhibit improved heat dissipation performance, electrical isolation performance and shows inhibition of delamination or cracking of the second routing circuitry deposited thereon or interfaces due to low CTE. Additionally, the maximum particle size of the thermally conductive fillers may be 25 μm or less. For binding the leadframe to the peripheral edges of the first routing circuitry, a second binding resin may be further provided to contact and bind the interior sidewall surface of the first binding resin and the peripheral edges of the first routing circuitry. Preferably, the top surface of the second binding resin is substantially coplanar with the top surface of the first binding resin and the top sides of the metal leads, whereas the bottom surface of the second binding resin is substantially coplanar with the bottom surface of the first binding resin, the top sides of the metal leads and the exterior surfaces of the second electrical conductors.

The optional metal alignment guide can be connected to the metal frame through tie bars and located between the first routing circuitry and the metal leads. Preferably, the bottom side of the metal alignment guide is substantially coplanar with the bottom sides of the metal leads and the exterior surfaces of the second electrical conductors. Additionally, the interior sidewall surface of the metal alignment guide can define an area with the same or similar topography as the first routing circuitry. As a result, the interior sidewall surface of the metal alignment guide in close proximity to the peripheral edges of the first routing circuitry can be used for the placement accuracy of the first routing circuitry and prevent the lateral displacement of the first routing circuitry.

The first routing circuitry can be formed on a detachable sacrificial carrier to form a subcomponent, followed by binding the subcomponent to the leadframe. Specifically, the first routing circuitry may be a multi-layered buildup circuitry without a core layer and formed to include a routing layer on the sacrificial carrier, a dielectric layer on the routing layer and the sacrificial carrier, and a wiring layer that extend from selected portions of the routing layer and fill up via openings in the dielectric layer to form metallized vias and laterally extend on the dielectric layer. Further, the first routing circuitry may include additional dielectric layers and additional wiring layers serially formed in an alternate fashion if needed for further signal routing. By removal of the sacrificial carrier after formation of the second routing circuitry, a cavity can be formed and laterally surrounded by the leadframe. Accordingly, a semiconductor device can be positioned within the cavity and electrically coupled to the first electrical conductors located at the bottom of the cavity and exposed from the cavity. Alternatively, the first routing circuitry may a thickness substantially equal to that of the leadframe and include an interconnect substrate, a first buildup circuitry and a second buildup circuitry. The first and second buildup circuitries are disposed on both opposite sides of the interconnect substrate. The interconnect substrate can include a core layer, first and second routing layers respectively on both opposite sides of the core layer, and metallized through vias formed through the core layer to provide electrical connection between the first and second routing layers. Each of the first and second buildup circuitries typically includes a dielectric layer and one or more conductive traces. The dielectric layers of the first and second buildup circuitries are respectively deposited on opposite sides of the interconnect substrate. The conductive traces extend laterally on the dielectric layer and include metallized vias in contact with first and second routing layers of the interconnect substrate. Further, the first and second buildup circuitries can include additional dielectric layers and additional conductive traces serially formed in an alternate fashion if needed for further signal routing. Accordingly, the outmost conductive traces at the opposite sides of the first routing circuitry can provide the first electrical conductors for device connection and the second electrical conductors for next-level routing connection, respectively.

The second routing circuitry may be a multi-layered buildup circuitry without a core layer and provide further fan-out routing/interconnection for the first routing circuitry and electrical connection with the metal leads. As the second routing circuitry can be electrically coupled to the first routing circuitry, the metal leads and optionally to the metal alignment guide through metallized vias of the second routing circuitry, the electrical connections between the first routing circuitry and the second routing circuitry and between the metal leads and the second routing circuitry and optionally between the metal alignment guide and the second routing circuitry can be devoid of soldering material. Also, the interface between the leadframe and the second routing circuitry can be devoid of solder or adhesive. More specifically, the second routing circuitry can be formed to include a dielectric layer on the first routing circuitry and the leadframe, and a wiring layer that extends from the second electrical conductors of the first routing circuitry, the metal leads and the optional metal alignment guide and fills up via openings in the dielectric layer of the second routing circuitry and laterally extends on the dielectric layer of the second routing circuitry. As a result, the second routing circuitry can contact and be electrically coupled to the second electrical conductors of the first routing circuitry and the metal leads for signal routing and optionally to the metal alignment for ground connection. Further, the second routing circuitry may include additional dielectric layers and additional wiring layers serially formed in an alternate fashion if needed for further signal routing. The outmost wiring layer of the second routing circuitry can accommodate conductive joints, such as solder balls, for electrical communication and mechanical attachment with for the next level assembly or another electronic device.

The sacrificial carrier, which provides rigidity support for the first routing circuitry, can be detached from the first routing circuitry by a chemical etching process or a mechanical peeling process after the formation of the second routing circuitry. The sacrificial carrier may be made of any conductive or non-conductive material, such as copper, nickel, chromium, tin, iron, stainless steel, silicon, glass, graphite, plastic film, or other metal or non-metallic materials. For the aspect of detaching the sacrificial carrier by a chemical etching process, the sacrificial carrier typically is made of chemically removable materials. In consideration of the first electrical conductors in contact with the sacrificial carrier not being etched during removal of the sacrificial carrier, the sacrificial carrier may be made of nickel, chromium, tin, iron, stainless steel, or any other material that can be removed using an etching solution inactive to the first electrical conductors made of copper. Alternatively, the first electrical conductors are made of any stable material against etching during removal of the sacrificial carrier. For instance, the first electrical conductors may be gold pads in the case of the sacrificial carrier being made of copper. Additionally, the sacrificial carrier also can be a multi-layer structure having a barrier layer and a support sheet, and the first routing circuitry is formed on the barrier layer of the sacrificial carrier. As the first routing circuitry is spaced from the support sheet by a barrier layer disposed therebetween, the support sheet can be removed without damage on the routing layer of the first routing circuitry even the routing layer and the support sheet are made of the same material. The barrier layer may be a metal layer that is inactive against chemical etching during chemically removing the support sheet and can be removed using an etching solution inactive to the routing layer. For instance, the support sheet made of copper or aluminum may be provided with a nickel, chromium or titanium layer as the barrier layer on its surface, and the routing layer made of copper or aluminum are deposited on the nickel, chromium or titanium layer. Accordingly, the nickel, chromium or titanium layer can protect the routing layer from etching during removal of the support sheet. As an alternative, the barrier layer may be a dielectric layer that can be removed by, for example, a mechanical peeling or plasma ashing process. For instance, a release layer may be used as a barrier layer disposed between the support sheet and the first routing circuitry, and the support sheet can be removed together with the release layer by a mechanical peeling process.

The present invention also provides a semiconductor assembly in which a first semiconductor device is electrically coupled to the first electrical conductors of the aforementioned wiring board. In a preferred embodiment, the first semiconductor device is positioned in the cavity of the wiring board and electrically connected to the wiring board using various using a wide variety of connection media such as bumps on the first electrical conductors of the wiring board. The first semiconductor device can be a packaged or unpackaged chip. For instance, the first semiconductor device can be a bare chip, or a wafer level packaged die, etc. Alternatively, the first semiconductor device can be a stacked-die chip. Additionally, a second semiconductor device may be further provided and electrically coupled to the metal leads of the wiring board using conductive joints such as solder balls. Accordingly, the present invention can provide a package-on-package assembly that includes a first semiconductor device positioned in the cavity of the wiring board and electrically coupled to the first electrical conductors of the wiring board, and a second semiconductor device positioned above the first semiconductor device and electrically coupled to the metal leads of the wiring board.

The term “cover” refers to incomplete or complete coverage in a vertical and/or lateral direction. For instance, in a preferred embodiment, the second routing circuitry covers the first routing circuitry and the leadframe regardless of whether additional elements are between the first routing circuitry and the second routing circuitry and between the leadframe and the second routing circuitry.

The phrase “aligned with” refers to relative position between elements regardless of whether elements are spaced from or adjacent to one another or one element is inserted into and extends into the other element. For instance, the metal alignment guide is laterally aligned with the first routing circuitry since an imaginary horizontal line intersects the metal alignment guide and the first routing circuitry, regardless of whether another element is between the metal alignment guide and the first routing circuitry and is intersected by the line, and regardless of whether another imaginary horizontal line intersects the first routing circuitry but not the metal alignment guide or intersects the metal alignment guide but not the first routing circuitry.

The phrase “in close proximity to” refers to a gap between elements not being wider than the maximum acceptable limit. As known in the art, in some cases, once the location error of the first routing circuitry goes beyond the maximum limit, it is impossible to align the predetermined portion of the first routing circuitry with a laser beam, resulting in the electrical connection failure between the first routing circuitry and the second routing circuitry. According to the pad size of the second electrical conductors, those skilled in the art can ascertain the maximum acceptable limit for a gap between the first routing circuitry and the metal alignment guide or the interior sidewall surface of the aperture of the leadframe through trial and error to ensure the metallized vias being of the second routing circuitry aligned with the second electrical conductors of the first routing circuitry. Thereby, the description “the interior sidewall surface of the aperture of the leadframe (or the interior sidewall surface of the first binding resin) is in close proximity to the peripheral edges of the first routing circuitry” means that the gap between the peripheral edges of the first routing circuitry and the interior sidewall surface of the aperture (or the interior sidewall surface of the first binding resin) is narrow enough to prevent the location error of the first routing circuitry from exceeding the maximum acceptable error limit. Likewise, the description “the interior sidewall surface of the metal alignment guide is in close proximity to the peripheral edges of the first routing circuitry” means that the gap between the peripheral edges of the first routing circuitry and the interior sidewall surface of the metal alignment guide is narrow enough to prevent the location error of the first routing circuitry from exceeding the maximum acceptable error limit. For instance, the gap in between the peripheral edges of the first routing circuitry and the interior sidewall surface of the aperture of the leadframe or between the peripheral edges of the first routing circuitry and the interior sidewall surface of the metal alignment guide preferably may be in a range of about 10 to 50 microns.

The phrases “electrical connection”, “electrically connected” and “electrically coupled” refer to direct and indirect electrical connection. For instance, in a preferred embodiment, the second routing circuitry directly contacts and is electrically connected to the metal leads, whereas the first routing circuitry is spaced from and electrically connected to the metal leads by the second routing circuitry.

The wiring board made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a wiring board, comprising:
providing a first routing circuitry that includes first electrical conductors and second electrical conductors at two opposite sides thereof, respectively, wherein the first electrical conductors and the second electrical conductors are electrically connected to each other;
providing a leadframe that laterally surrounds the first routing circuitry and includes a plurality of metal leads and a first binding resin, wherein the first binding resin fills in spaces between the metal leads; and
forming a second routing circuitry that is disposed over the first routing circuitry and laterally extends over the leadframe, wherein the second routing circuitry includes at least one dielectric layer and at least one wiring layer in an alternate fashion, and the wiring layer of the second routing circuitry is electrically coupled to the second electrical conductors of the first routing circuitry and the metal leads.

2. The method of claim 1, wherein the step of providing the leadframe includes:
providing a metal frame, the metal leads and a sacrificial block, wherein the sacrificial block is within the metal frame, and the metal leads are integrally connected to the metal frame;
depositing the first binding resin that fills in remaining spaces within the metal frame; and
removing the sacrificial block to form an aperture for accommodating the first routing circuitry therein.

3. The method of claim 1, further comprising a step of disposing a second binding resin into a space between the leadframe and the first routing circuitry before forming the second routing circuitry.

4. The method of claim 1, wherein (i) the step of providing the first routing circuitry includes forming the first routing circuitry on a detachable sacrificial carrier, (ii) the leadframe also laterally surrounds peripheral edges of the detachable sacrificial carrier, and (iii) the detachable sacrificial carrier is removed to from a cavity from which the first electrical connectors of the first routing circuitry are exposed after the step of forming the second routing circuitry.

5. A method of making a wiring board, comprising:
providing a first routing circuitry that includes first electrical conductors and second electrical conductors at two opposite sides thereof, respectively, wherein the first electrical conductors and the second electrical conductors are electrically connected to each other;
providing a leadframe that laterally surrounds the first routing circuitry and includes a plurality of metal leads; and
forming a second routing circuitry that is disposed over the first routing circuitry and laterally extends over the leadframe, wherein the second routing circuitry includes at least one dielectric layer and at least one wiring layer in an alternate fashion, and a portion of the dielectric layer fills in spaces between the metal leads and binds peripheral edges of the first routing circuitry, and the wiring layer is electrically coupled to the second electrical conductors of the first routing circuitry and the metal leads.

6. The method of claim 5, wherein the step of providing the leadframe includes providing a metal frame and the metal leads, and the metal leads are integrally connected to the metal frame.

7. The method of claim 6, wherein the step of providing the leadframe further includes providing a metal alignment guide within the metal frame, and the metal alignment guide are laterally aligned with the peripheral edges of the first routing circuitry.

8. The method of claim 5, wherein (i) the step of providing the first routing circuitry includes forming the first routing circuitry on a detachable sacrificial carrier, (ii) the leadframe also laterally surrounds peripheral edges of the detachable sacrificial carrier, and (iii) the detachable sacrificial carrier is removed to from a cavity from which the first electrical connectors of the first routing circuitry are exposed after the step of forming the second routing circuitry.
